(19) United States
(12) Patent Application Publication
(10) Pub. No.: US 2008/0261157 A1
(43) Pub. Date: Oct. 23, 2008

(54) SEMICONDUCTOR LASER DEVICE AND METHOD OF MANUFACTURING THE SAME

(75) Inventors: Yong Tak LEE, Gwangju (KR); Sung Jun Jang, Gwangju (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Gwangju Institute of Science and Technology, Gwangju (KR)

(21) Appl. No.: 12/018,697

(22) Filed: Jan. 23, 2008

(30) Foreign Application Priority Data
Jan. 23, 2007 (KR) 10-2007-0006908

(51) Int. Cl. H01L 21/311; H01L 21/02

(52) U.S. Cl. 430/314; 430/319

(57) ABSTRACT

Disclosed is a method of manufacturing a distributed feedback semiconductor laser device. In order to form a grating in only a channel, an etching mask, which is used when forming a ridge waveguide, is allowed to remain. A portion of sides of an ohmic contact layer is removed. A metal layer that remains at locations other than a location of the grating is removed by a lift-off method. According to an embodiment of the invention, a holographic exposure method or a nanoimprint method is used in forming a grating of the distributed feedback laser device, and the grating is formed in a self-aligned manner. The distributed feedback laser device that is manufactured according to the embodiment of the invention can be formed by using a technology and a structure that are suitable for mass production. Further, excellent reproducibility can be ensured and production costs can be decreased in the distributed feedback laser device, thereby complementing a disadvantage of an existing distributed feedback laser device.

### BACKGROUND OF THE INVENTION

1. Technical Field

The present invention relates to a semiconductor laser device, and more particularly, to a method of manufacturing a ridge waveguide DFB-LD (Distributed Feedback Laser Diode).

2. Related Art

In the case of a DFB-LD (Distributed Feedback Laser Diode), a buried hetero structure having a superior single mode characteristic has been generally used. However, since a regrowth process needs to be performed, the DFB-LD is disadvantageous as compared with a ridge waveguide structure in terms of production costs or a yield. Accordingly, in recent years, various researches have been made on a ridge waveguide DFB-LD that can be manufactured at low costs. In the case of the buried hetero structure, since a regrowth process needs to be performed after forming a grating, it is general to form the grating by etching a semiconductor substrate. In this grating, refractive index coupling is made. A research result, which represents that the refractive index coupling by the grating is disadvantageous as compared with gain coupling by a metal grating in terms of a single mode yield, has been reported.

In general, the ridge waveguide DFB-LD operates in a single mode through coupling between beams guided along the ridge waveguide and a grating just beside the ridge waveguide, and thus it is important for the grating to be accurately formed just beside the ridge waveguide. Since the ridge waveguide protrudes on the substrate, an electron beam exposure method (for example, E-beam lithography) is mainly used to form the grating at both sides of the ridge waveguide. However, since the electron beam exposure method needs a large amount of exposure time, it is not suitable at the time of mass production and when manufacturing a low-priced laser. A holographic exposure method (for example, holographic lithography) that has been researched as the alternative of the electron beam exposure method is suitable for mass production in that an exposure time is short and an area is not limited. However, when a protruding structure, such as the waveguide, exists on the substrate, it is difficult to accurately form the grating at both sides of the waveguide. Since the entire substrate is exposed at a time, it is difficult to form the grating only at desired portions.

FIG. 1A is a diagram illustrating a part of a process of manufacturing a ridge waveguide distributed feedback laser device using holographic exposure according to the related art.

FIG. 1B is a scanning election micrograph (SEM) illustrating a state where a grating is formed on a substrate on which a ridge waveguide formed by a process shown in FIG. 1A exists.

The related art shown in FIG. 1A relates to a method in which a photoresist is applied at a small thickness. Referring to FIG. 1A, an active layer 120 and a cladding layer 130 are sequentially formed on a semiconductor substrate 110 to form a ridge waveguide. An ohmic contact layer (not shown) is formed on the cladding layer 130. In the method according to the related art, after applying a photoresist on the obtained structure at a small thickness, a self-aligned mask 140 for the grating is formed by holographic exposure. The reason why the photoresist is applied at a small thickness and the self-aligned mask 140 is formed through the holographic exposure is to form the metal grating by using only a lift-off process without performing an additional process. However, when the photoresist is applied at a small thickness, it is difficult to accurately form a pattern on the irregular substrate structure, as can be seen from FIGS. 1A and 1B. That is, as can be seen from FIG. 1A, it is difficult to completely remove the photoresist at portions where the grating is to be formed, and the photoresist may remain at sides of the cladding layer 130.

FIG. 2A is a diagram illustrating a part of a process of manufacturing a ridge waveguide distributed feedback laser device using holographic exposure according to the related art. FIG. 2B is a scanning election micrograph (SEM) illustrating a state where a grating is formed on a substrate on which a ridge waveguide formed by a process shown in FIG. 2A exists.

Specifically, FIG. 2A shows a method according to another example of the related art in which a photoresist is applied at a large thickness. Referring to FIG. 2A, an active layer 220 and a cladding layer 230 are sequentially formed on a semiconductor substrate 210 to form a ridge waveguide, in the same method as that in FIG. 1A. An ohmic contact layer (not shown) is formed on the cladding layer 230. In this case, a photoresist is applied at a large thickness on the obtained structure. Then, holographic exposure and development are performed to form a self-aligned mask 240 having a concavo-convex shape so as to form a grating. In this case, since the photoresist is formed thick, a concave portion (‘B’ in FIG. 2A) is not completely removed by the holographic exposure and development. The portion B that corresponds to the remaining photoresist is removed by anisotropic etching, which results in planarizing a portion where the grating is formed. However, according to the related art, as can be seen from FIG. 2B, the grating is formed on the ohmic contact layer formed on the ridge waveguide, that is, the cladding layer 230, and thus it causes resistance to increase, which deteriorates the performance.

### SUMMARY OF THE INVENTION

The invention has been finalized in order to solve the above-described problems. It is an object of the invention to provide a method of manufacturing a distributed feedback semiconductor laser device in which a grating is formed in only a channel.

According to an aspect of the invention, there is provided a method of manufacturing a distributed feedback semiconductor laser device in which a ridge waveguide is stacked on a semiconductor substrate. The method includes providing the semiconductor substrate on which a lower structure including an active layer is formed; forming on the lower structure of the semiconductor substrate, a prominent laminated structure including a cladding layer, an ohmic contact layer, and a mask layer sequentially formed; forming a self-aligned mask layer of a photoresist that is formed on an entire surface of the semiconductor substrate and exposes portions which correspond to sides of the cladding layer and where a grating is formed; depositing a metal layer for forming the grating on the entire surface of the semiconductor substrate where the self-aligned mask layer is formed; and removing the self-aligned mask layer and the mask layer and removing the metal layer for the grating formed thereon by a lift-off process so as to form the grating.

The mask layer may be a residue of an etching mask that is used when patterning the cladding layer and the ohmic contact layer.

The etching mask may be an oxide film.

The forming of the laminated structure on the lower structure of the semiconductor substrate may include selectively removing a portion of sides of the ohmic contact layer by isotropic etching.

The portions where the grating is to be formed may be exposed by the isotropic etching.

The forming of the self-aligned mask layer of the photoresist may include forming the photoresist on the laminated structure to be relatively flat; forming a concavo-convex shape on the photoresist; selectively forming a metal mask layer on only convex portions of the photoresist; and selectively removing concave portions of the photoresist using the metal mask layer as a mask to exposure the portions where the grating is formed.

The concavo-convex shape may be formed on the photoresist by a holographic exposure method.

When the metal mask layer is formed, depositing a portion of the metal mask layer by inclining the semiconductor substrate for one side to upward and depositing another portion of the metal mask layer by inclining the semiconductor substrate for the other side to upward may be repeatedly performed by one or more times.

The concave portions of the photoresist may be removed by ion etching.

The forming of the self-aligned mask layer of the photoresist may be performed by using a nanoimprint method.

The lower structure may include an etching stopper layer that is formed on an uppermost surface.

The lower structure may include the active layer, a spacer layer, and an etching stopper layer that are sequentially laminated on the semiconductor substrate.

### BRIEF DESCRIPTION OF THE DRAWINGS

FIG. 1A is a diagram illustrating a part of a process of manufacturing a ridge waveguide distributed feedback laser device using holographic exposure according to the related art;

FIG. 1B is a scanning election micrograph (SEM) illustrating a state where a grating is formed on a substrate on which a ridge waveguide formed by a process shown in FIG. 1A exists;

FIG. 2A is a diagram illustrating a part of a process of manufacturing a ridge waveguide distributed feedback laser device using holographic exposure according to the related art;

FIG. 2B is a scanning election micrograph illustrating a state where a grating is formed on a substrate on which a ridge waveguide formed by a process shown in FIG. 2A exists;

FIGS. 3A to 3L are diagrams illustrating a process of manufacturing a semiconductor laser device according to an embodiment of the invention;

FIG. 4 is a cross-sectional view illustrating the utility of undercut of an ohmic contact layer that is used in a method of manufacturing a semiconductor laser device according to an embodiment of the invention;

FIG. 5 is a scanning election micrograph illustrating a distributed feedback laser device having a double channel waveguide structure that is manufactured according to an embodiment of the invention; and

FIG. 6 is a diagram illustrating a coupling coefficient of a grating with respect to a refractive index of a material that forms a protective film.

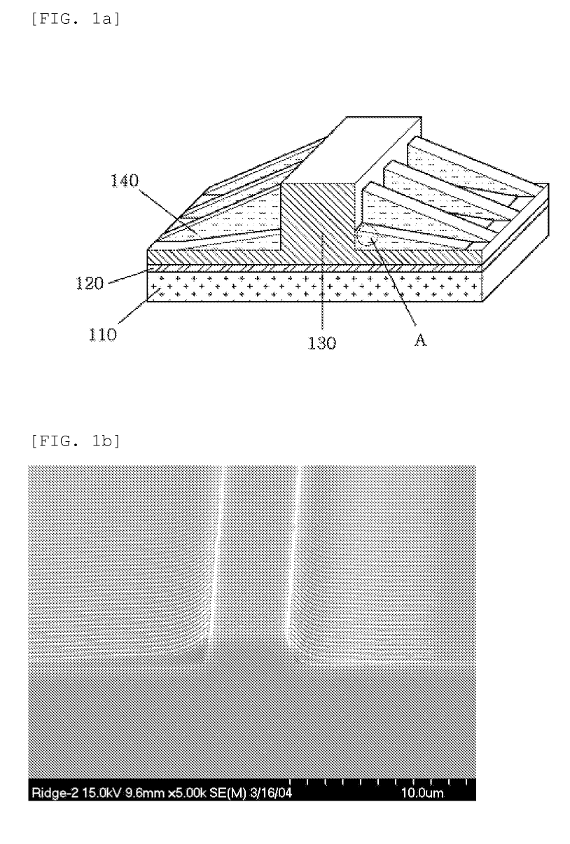

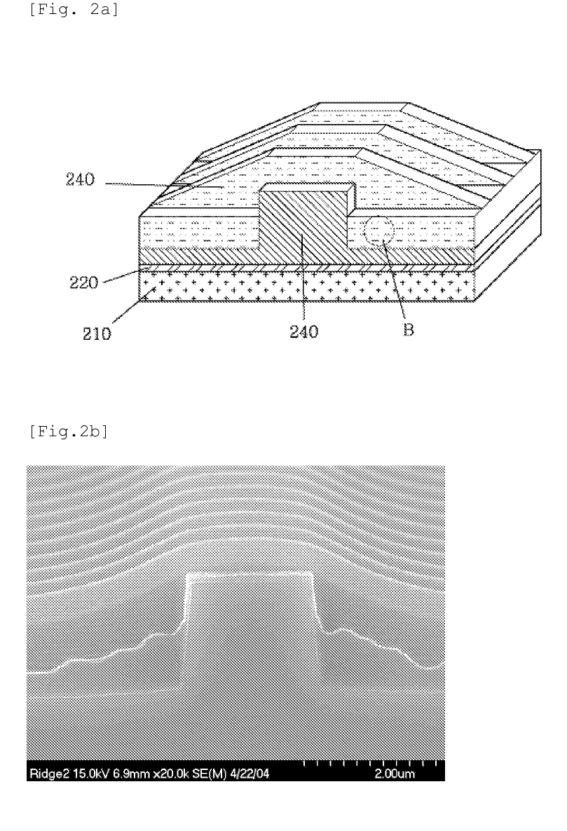

### DESCRIPTION OF EXEMPLARY EMBODIMENT

Hereinafter, exemplary embodiments of the invention will be described in detail with reference to the accompanying drawings. It should be noted that the same components are represented by the same reference numerals even if they are shown in different drawings. In the embodiment of the invention, detailed description of known structures and functions incorporated herein will be omitted when it may make the subject matter of the invention unclear.

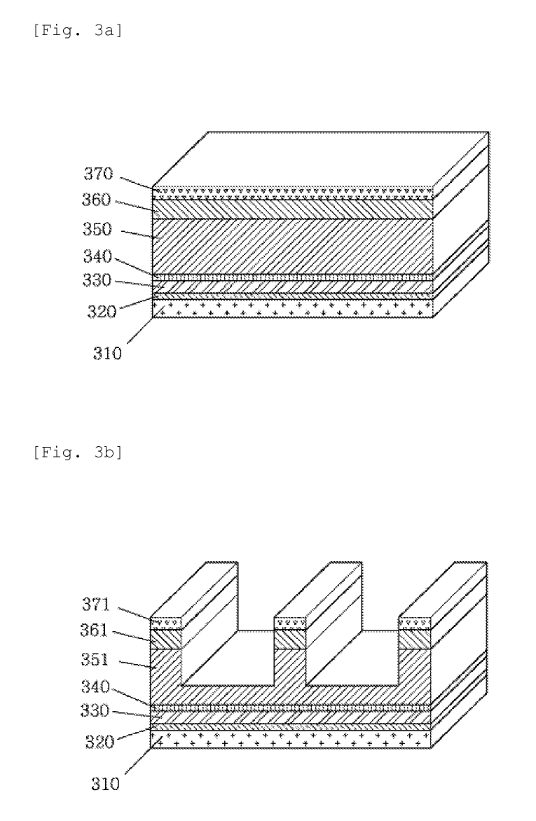

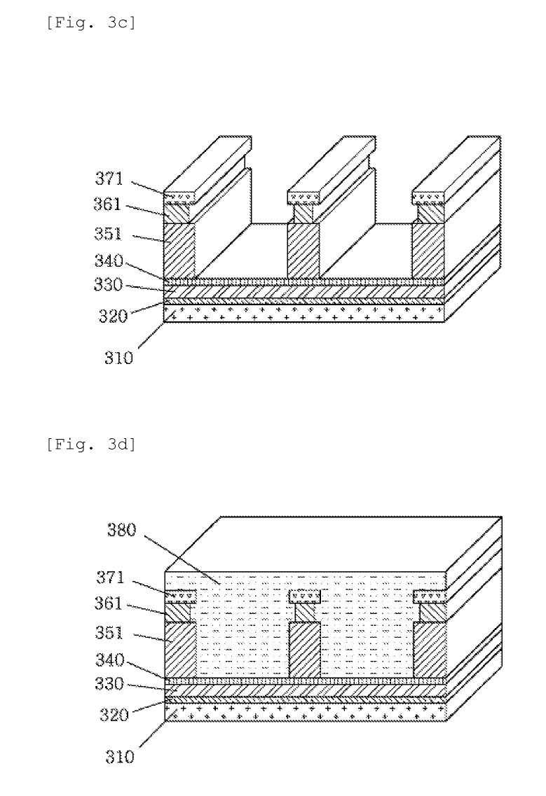

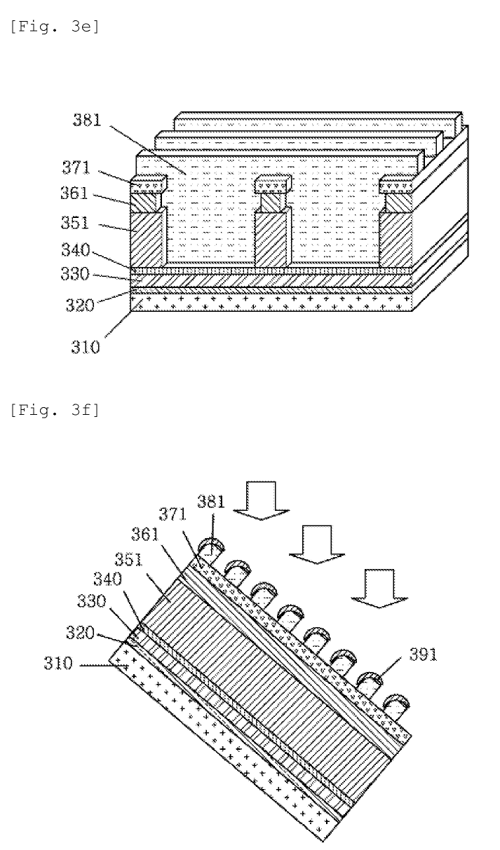

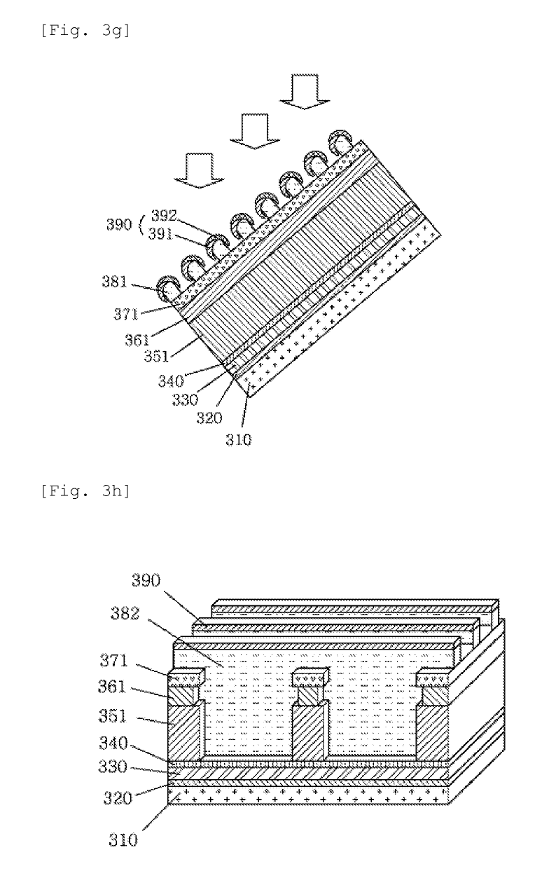

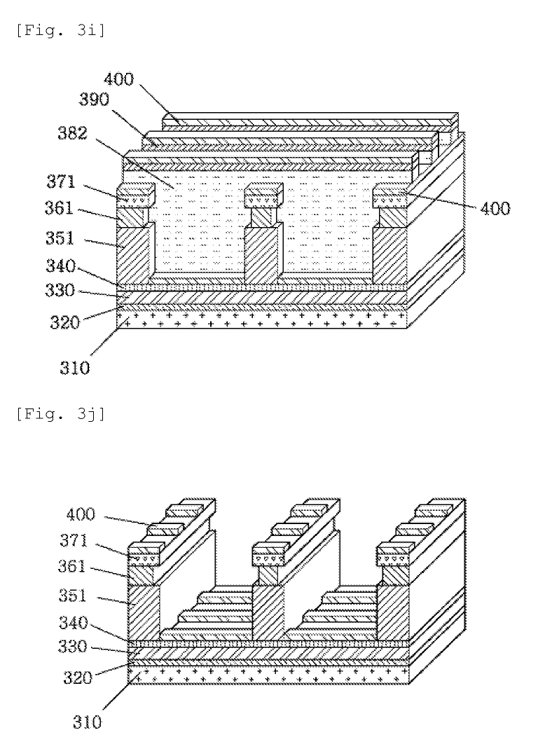

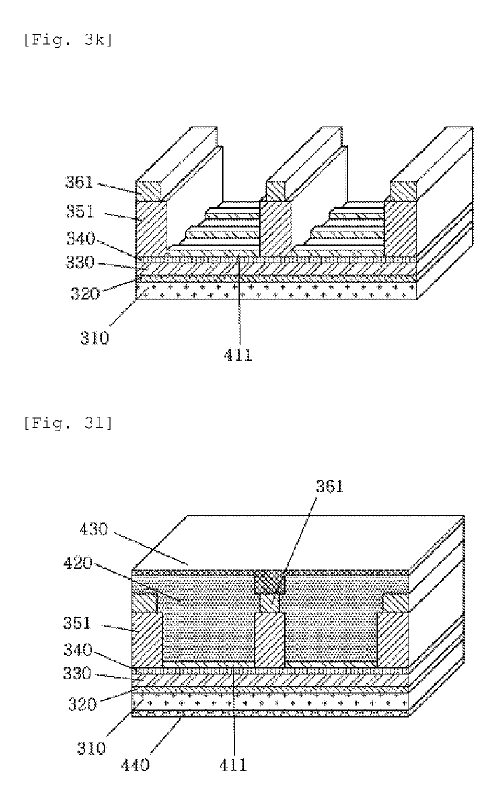

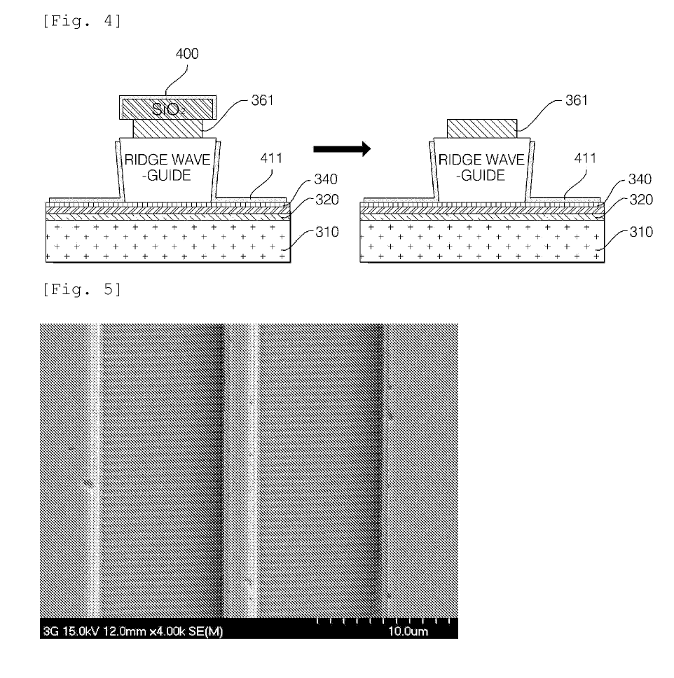

FIGS. 3A to 3L are diagrams illustrating a process of manufacturing a semiconductor laser device according to an embodiment of the invention. In the embodiment described below, the detailed description of an unimportant portion in a process of manufacturing a laser diode will be omitted, and only the scope of the invention will be described in detail. In the drawings, the thickness of individual material layers is arbitrary, and does not mean the actual or proportional thickness of the individual material layers.

First, as shown in FIG. 3A, an active layer 320, a spacer layer 330, an etching stopper layer 340, a cladding material layer 350 used to form a cladding layer, and an ohmic contact material layer 360 used to form an ohmic contact layer are sequentially formed on a semiconductor substrate 310 that is made of, for example, n-InP.

In this case, structures that are formed below the cladding material layer 350 may be generically referred to as a lower structure. The lower structure is a laminated structure that includes at least the active layer 320, and the active layer 320 may include a lower waveguide, a quantum well, and an upper waveguide.

The active layer 320 may be formed of AlGaAs, InGaAsP, InGaAs, or InAs. The etching stopper layer 340 may be formed of InGaAsP. The cladding material layer 350 may be formed of AlGaAs, InP, InAlAs, or InGaAlP. The ohmic contact material layer 360 may be formed of GaAs or InGaAs, and the spacer layer 330 may be formed of the same material as the cladding material layer 350.

Referring back to FIG. 3A, a silicon oxide film 370, which is used as a mask at the time of etching a ridge waveguide, is deposited at a predetermined thickness over an entire top surface of the ohmic contact material layer 360.

Then, as shown in FIG. 3B, the deposited silicon oxide film 370 is patterned into an etching mask 371 in a form of a waveguide having a double channel. An ohmic contact layer 361 and a cladding layer 351 are formed by performing dry etching using the patterned etching mask 371. In this case, the etching mask 371 functions as a mask that is used to etch the ohmic contact layer and the cladding layer. Accordingly, the etching mask 371 may be referred to as a waveguide formation mask. As will be described below, to make the etching mask 371 remain up to a predetermined process is one of important portions of the invention. Also, the etching mask 371 may be referred to as an ohmic contact layer formation mask. In this embodiment, dry etching and wet etching are sequentially performed in forming a ridge waveguide structure.

Then, as shown in FIG. 3C, a portion of sides of the ohmic contact layer 361 is removed by using isotropic etching, such as wet etching. At this time, it is important to remove the portion of the sides of the ohmic contact layer 361 in a state where the etching mask 371 remains. The remaining etching mask 371 is to prevent a metal layer for a grating from being finally formed on the ohmic contact layer, which will be described in detail below. Further, the remaining etching mask 371 forms the undercut ohmic contact layer 361 at the time of isotropic etching. The ohmic contact layer 361 is formed such that the sides thereof are partially removed, in order that, when the grating is formed on the ohmic contact layer 361, the grating is removed while the etching mask 371 is removed, and the metal layer for the grating that may be formed at the sides of the waveguide is disconnected. At this time, the isotropic etching is performed to remove the cladding material layer remaining at the channel to expose the etching stopper layer 340, thereby forming the cladding layer 351. When the cladding layer 351 is formed, it is preferable that the portion of the cladding material layer be removed by the isotropic etching after the portion of the cladding material layer is allowed to remain, in terms of uniform removing of the cladding material layer. However, the invention is not limited thereto, and the cladding material layer may be completely removed in the process of FIG. 3B or the remaining portion of the cladding material layer may be removed in a subsequent process.

Preferably, in order to form the ridge waveguide structure, dry etching and wet etching are performed, and the undercut ohmic contact layer 361 is formed, as shown in FIG. 3C. However, the ridge waveguide structure may be formed by only using dry etching without performing the undercutting on the ohmic contact layer 361. Even in this case, the etching mask 371 remains. For enhancement of understanding, the ohmic contact layer 361 and the cladding layer 351 are denoted by the same reference numerals in FIGS. 3B and 3C.

Then, as shown in FIG. 3D, the photoresist 380 is applied to be thick and flat over the entire surface of the structure including the etching mask 371. At this time, the etching mask 371 remains to remove the metal grating material to be formed on the ohmic contact layer 361, as described above.

Then, the photoresist 380 that is applied to be entirely flat is exposed by using the holographic exposure method and then developed, or the photoresist 381 having a concavo-convex shape is formed by using a nanoimprint method, as shown in FIG. 3E.

At this time, the photoresist 380 that is applied to be flat as shown in FIG. 3D is applied such that the thickness of the photoresist 380 is larger than the height of the ridge waveguide. Thus, concave portions of the photoresist 381 obtained after being developed are not completely removed for the etching stopper layer 340 to be exposed.

In this case, if a shape inversion exposure method is used, it is possible to control a duty ratio of the metal grating to be formed. At the time of the shape inversion exposure, primary exposure is performed by using a holographic exposure device, and secondary exposure is performed over the entire surface after heat treatment. In this way, it is possible to form a concavo-convex pattern of the photoresist 381 whose duty ratio has been controlled.

Even in this case, if the nanoimprint method is used, it is possible to manufacture a multiwavelength distributed feedback laser array having a different period.

Then, as shown in FIGS. 3F and 3G, the metal mask layer 390 used to etch the concave portions of the photoresist 381 is selectively deposited on only convex portions of the photoresist 381. FIGS. 3F and 3G are side views. Preferably, as shown in FIG. 3F, the substrate is inclined for one side thereof to upward, and then deposition is performed to form a portion 391 of the metal mask layer. Then, as shown in FIG. 3G, the substrate is inclined for the other side thereof to upward, and then deposition is performed to form the other portion 392 of the metal mask layer. In this way, the metal mask layer 390 is selectively deposited on only the convex portions of the photoresist 381. In this embodiment, the selectively deposited metal mask layer 390 is inclined twice in different directions, and the metal mask layer is deposited and completed. However, different methods may be used according to an application range. Accordingly, the number of times of inclination or inclination may be changed.

Then, as shown in FIG. 3H, the concave and convex portions of the photoresist 381 are subjected to dry etching using the metal mask layer 390 for the etching stopper layer 340 to be exposed, thereby forming a self-aligned mask 382 for the grating. As such, after the photoresist is applied thick such that the structure is planarized, the portion of the photoresist is exposed and removed, and the other portion of the photoresist is etched using the metal mask layer 390. As a result, it is possible to ensure reproducibility in manufacturing the minute grating on the substrate whose surface is irregular due to the waveguide.

Then, as shown in FIG. 3I, a metal layer 400 for the grating, for example, a Cr layer is deposited on the resultant. The metal layer 400 is deposited on the top surface of the remaining etching mask 371 and the top surface of the self-aligned mask 382 for the grating as well as the channel.

Then, as shown in FIGS. 3J and 3K, only the metal grating 411 remains, and the metal layer 400 is removed. That is, as shown in FIG. 3J, while the self-aligned mask 382 for the grating that is the photoresist is removed through the lift-off method, the metal mask layer 390 formed on the self-aligned mask 382 is removed. Then, as shown in FIG. 3K, the oxide film that is used as the etching mask 371 is removed, and the metal layer 400 that is formed on the etching mask 371 is removed by the lift-off method. The metal grating 411 is formed in only the channel in the double channel waveguide structure. As a result, the metal layer, which is formed on the ohmic contact layer 361 by the photoresist that has been applied thick to accurately form the grating and thus serves as a resistor between a p-typed metal layer (refer to reference numeral 430 in FIG. 3L) and the ohmic contact layer 361, is removed. This method is to form the grating at a desired portion without performing an aligning process, and thus may be referred to as a self-aligned grating formation method.

FIG. 4 is a cross-sectional view illustrating the utility of undercut of an ohmic contact layer in a method of manufacturing a semiconductor laser device according to an embodiment of the invention. As can be seen from FIG. 4, in the metal layer for the grating at the undercut portion of the ohmic contact layer 361, the actual portion (refer to reference numeral 411) of the grating and a portion (refer to reference numeral 400) formed on the ohmic contact layer 361 are disconnected from each other.

Then, as shown in FIG. 3L, after a protective film 420 is formed on the resultant, the p-typed metal layer 430 and the n-typed metal layer 440 are respectively deposited on and below the resultant.

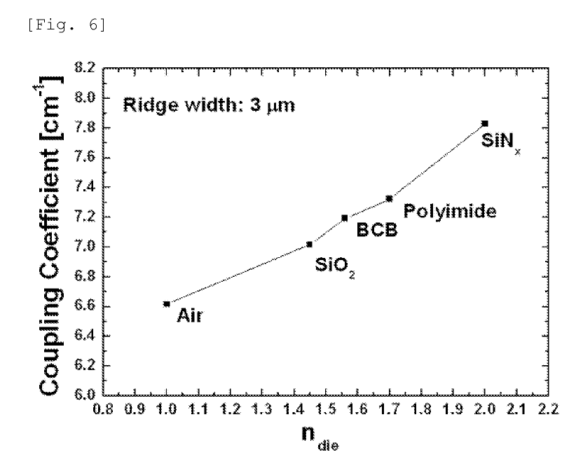

FIG. 5 is a scanning election micrograph (SEM) illustrating a distributed feedback laser device having a double channel waveguide structure that is manufactured according to an embodiment of the invention. As can be seen from FIG. 5, using the method according to the embodiment of the invention, the grating is formed in only the channel to be uniform.

Meanwhile, according to the experiment result, coupling efficiency of the grating 411 varies according to the material of the protective film 420, which is shown in FIG. 6.

FIG. 6 is a diagram illustrating a coupling coefficient of a grating with respect to a refractive index of a material that forms a protective film.

In the case of the distributed feedback laser diode, a specific single mode characteristic is determined by a coupling coefficient. Therefore, to obtain the coupling efficiency by the high coupling coefficient is very important in a stable single mode characteristic of the distributed feedback laser diode. As shown in FIG. 6, in this embodiment, the protective film may be formed of a material, such as silicon dioxide (SiO2), Benzocyclobutene (BCB), polyimide, or nitride silicon SiNx.

The nanoimprint method has been actively researched in recent years because it is suitable for mass production and a type of a pattern can be selected. Like the case where the distributed feedback laser diode is manufactured, when forming a minute pattern, process efficiency and reproducibility are ensured. When the nanoimprint method is applied in manufacturing the laser device, it is possible to manufacture gratings for a multilwavelength distributed feedback laser array having different periods as well as a grating of a distributed feedback laser diode having the same period.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects. The scope of the present invention is defined by the appended claims rather than by the description preceding them, and all changes and modifications that fall within metes and bounds of the claims, or equivalents of such metes and bounds are therefore intended to be embraced by the claims.

According to the embodiment of the invention, a technology called holographic exposure that is epoch-making in mass production and reduction of manufacturing costs can be applied in manufacturing the ridge waveguide distributed laser diode, and a disadvantage in the holographic exposure can be complemented by using a self-aligned technology that enables the grating to be formed only at a desired portion. Therefore, when manufacturing the ridge waveguide distributed feedback laser diode having relatively low manufacturing costs, the manufacturing costs can be further reduced, and reproducibility can be ensured, which makes it possible to achieve a low-priced distributed feedback laser diode. Further, reproducibility when forming the minute pattern can be ensured by using the nanoimprint method, and a distributed feedback laser diode having a desired period can be manufactured, which can manufacture a low-priced multiwavelength distributed feedback laser diode.

What is claimed is:

1. A method of manufacturing a distributed feedback semiconductor laser device in which a ridge waveguide is stacked on a semiconductor substrate, the method comprising:
providing the semiconductor substrate on which a lower structure including an active layer is formed;
forming on the lower structure of the semiconductor substrate, a prominent laminated structure including a cladding layer, an ohmic contact layer, and a mask layer sequentially formed;
forming a self-aligned mask layer of a photoresist that is formed on an entire surface of the semiconductor substrate and exposes portions which correspond to sides of the cladding layer and where a grating is formed;
depositing a metal layer for forming the grating on the entire surface of the semiconductor substrate where the self-aligned mask layer is formed; and
removing the self-aligned mask layer and the mask layer and removing the metal layer for the grating formed thereon by a lift-off process so as to form the grating.

2. The method of claim 1,
wherein the mask layer is a residue of an etching mask that is used when patterning the cladding layer and the ohmic contact layer.

3. The method of claim 2,
wherein the etching mask is an oxide film.

4. The method of claim 1,
wherein the forming of the laminated structure on the lower structure of the semiconductor substrate includes selectively removing a portion of sides of the ohmic contact layer by isotropic etching.

5. The method of claim 4,
wherein the portions where the grating is to be formed are exposed by the isotropic etching.

6. The method of claim 1,
wherein the forming of the self-aligned mask layer of the photoresist includes:
forming the photoresist on the laminated structure to be relatively flat;
forming a concavo-convex shape on the photoresist;
selectively forming a metal mask layer on only convex portions of the photoresist; and
selectively removing concave portions of the photoresist using the metal mask layer as a mask to exposure the portions where the grating is formed.

7. The method of claim 6,
wherein the concavo-convex shape is formed on the photoresist by a holographic exposure method.

8. The method of claim 7,
wherein, when the metal mask layer is formed, depositing a portion of the metal mask layer by inclining the semiconductor substrate for one side to upward and depositing another portion of the metal mask layer by inclining the semiconductor substrate for the other side to upward are repeatedly performed by one or more times.

9. The method of claim 6,
wherein the concave portions of the photoresist are removed by ion etching.

10. The method of claim 6,
wherein the forming of the self-aligned mask layer of the photoresist is performed by using a nanoimprint method.

11. The method of claim 1,
wherein the lower structure includes an etching stopper layer that is formed on an uppermost surface.

12. The method of claim 1,
wherein the lower structure includes the active layer, a spacer layer, and an etching stopper layer that are sequentially laminated on the semiconductor substrate.

13. The method of claim 1, further comprising:
forming a protective film on a resultant obtained by the providing of the semiconductor substrate to the removing of the self-aligned mask layer and the mask layer and the removing of the metal layer for the grating formed thereon by the lift-off process so as to form the grating, and depositing a p-typed metal layer and an n-typed metal layer on and below the resultant, respectively.

14. The method of claim 13,
wherein coupling efficiency of a grating layer is changed by changing a material of the protective film.

15. The method of claim 14,
wherein the protective film is an oxide film, a nitride film or a polymer material.

16. A semiconductor laser device manufactured by the method of any one of claims 1 to 15.

17. A method of manufacturing a distributed feedback semiconductor laser device, the method comprising:
sequentially forming an active layer, a spacer layer, an etching stopper layer, a cladding material layer, and an ohmic contact material layer on a semiconductor substrate;
forming an etching mask made of an oxide film on the ohmic contact material layer;
forming an ohmic contact layer and a cladding layer by etching the ohmic contact material layer and the cladding material layer to form a ridge waveguide structure having a channel formed at both sides;
applying a photoresist in a state where the etching mask remains;
forming concave and convex shapes to form a grating in the photoresist using holographic exposure and development;
selectively forming a metal mask layer on convex portions of the photoresist;
selectively removing concave portions of the photoresist using the metal mask layer such that a predetermined region of the etching stopper layer is exposed;
depositing a metal layer used for the grating on an entire surface including the photoresist where the concave portions are removed;
removing the remaining photoresist and the metal mask layer on the photoresist by using a lift-off process; and
removing the metal layer formed on the etching mask while removing the etching mask and forming the grating at both sides of the ridge waveguide structure.

18. The method of claim 17,
wherein the forming of the ohmic contact layer and the cladding layer by etching the ohmic contact material layer and the cladding material layer to form the ridge waveguide structure includes performing dry etching primarily using the etching mask and wet etching secondarily to remove a portion of sides of the ohmic contact layer.

19. The method of claim 18,
wherein the etching of the cladding material layer using the dry etching is performed to the extent that the etching stopper layer is not exposed, and the wet etching is performed such that the etching stopper layer is exposed.

20. The method of claim 17,
wherein, in the selective forming of the metal mask layer on the convex portions of the photoresist, depositing a portion of the metal mask layer by inclining the semiconductor substrate for one side to upward and depositing another portion of the metal mask layer by inclining the semiconductor substrate for the other side to upward are repeatedly performed by one or more times.

21. The method of claim 17, further comprising:
forming a protective film on a resultant obtained by the sequential forming of the active layer, the spacer layer, the etching stopper layer, the cladding material layer, and the ohmic contact material layer on the semiconductor substrate to the forming of concave and convex shapes to form the grating in the photoresist using the holographic exposure and development, and depositing a p-typed metal layer and an n-typed metal layer on and below the resultant, respectively.

22. The method of claim 21,
wherein coupling efficiency of a grating layer is changed by changing a material of the protective film.

23. The method of claim 12,
wherein the protective film is an oxide film, a nitride film or a polymer material.

24. A semiconductor laser device manufactured by the method of any one of claims 17 to 23.
